(19) United States
(12) Patent Application Publication
(10) Pub. No.: US 2003/0102917 A1
(43) Pub. Date: Jun. 5, 2003

(54) Output stage configuration of an operational amplifier

(76) Inventor: Tao Wu, Waukegan, IL (US)

Correspondence Address: MOTOROLA INC, 600 NORTH US HIGHWAY 45, LIBERTYVILLE, IL, 60048-5343, US

(21) Appl. No.: 10/004,569

(22) Filed: Dec. 5, 2001

(51) Int. Cl. H03F 3/45; H03F 1/14

(52) U.S. Cl. 330/260; 330/292

(57) ABSTRACT

An operational amplifier (op-amp) having a stage in parallel, dummy stage (212), with a final output stage (208) coupled to an initial stage (206). The dummy stage provides a desired Miller capacitance to the initial stage to isolates noise coupling between the power supply (214) and the output (204) and to improve the stability of the op-amp. By providing the dummy stage, the total capacitance required to achieve the desired noise isolation and stability is reduced thereby reducing the area required to implement the op-amp on an integrated circuit die.

### FIELD OF THE INVENTION

The present invention generally relates to the field of electronic devices. More specifically, the present invention relates to semiconductor devices used in such applications as voltage reference and voltage buffer.

### BACKGROUND OF THE INVENTION

In large integrated circuit (IC), a voltage buffer using an operational amplifier (op-amp) is often used to provide a voltage reference to other parts of the IC. One major area of concern in providing a voltage reference using an op-amp is noise coupling from the power supply of the op-amp to the second stage output of the op-amp where it provides the voltage reference. One example of conventional circuit topologies for an op-amp used as a voltage buffer is to provide a capacitor between the power supply of the op-amp and the first stage output of the op-amp. This topology can provide a desired power supply rejection ratio (PSRR), however, the capacitance must be large in order to provide circuit stability while achieving a reasonable PSRR. A large capacitance is undesirable because it requires a large space on a die of the IC. Another example of conventional topologies is to provide a Miller capacitor between the second stage input and the second stage output while having the first stage output coupled to the second stage input. This topology provides desired circuit stability, however, the PSRR performance is less effective than that of the first example. One may combine both topologies in order to attempt to realize both advantages of the PSRR performance of the first example and the stability performance of the second example. However the combined topology, providing a capacitor between the power supply and the first stage output in addition to providing a Miller capacitor between the second stage input and the second stage output, suffers from noise coupling between the second stage output and the power supply. Accordingly, there is a need for an op-amp having high PSRR performance while providing stability without requiring a large capacitance.

### BRIEF DESCRIPTION OF THE DRAWINGS

FIG. 1 illustrates a block diagram representation of a prior art circuit; and,

FIG. 2 illustrates a block diagram representation of the preferred embodiment of the present invention.

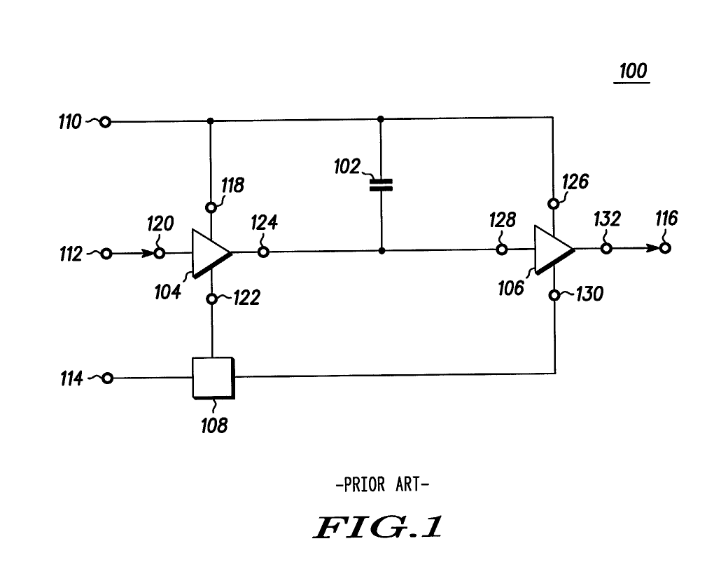

### SUMMARY OF THE INVENTION

The present invention describes an operational amplifier (op-amp) having a dummy output stage amplifier in parallel with its actual final stage amplifier coupled to the initial stage amplifier to improve the power supply rejection ratio (PSRR) performance and the noise coupling between the power supply and the output. The dummy stage provides a desired Miller capacitance to the initial stage without requiring a large capacitor, and isolates noise from the power supply line coupling to the output. By providing a capacitor between the power supply line and the input to the dummy stage, stability of the op-amp is also improved.

### DETAILED DESCRIPTION OF A PREFERRED EMBODIMENT

The present invention describes an output stage configuration for an operation amplifier (op-amp) having a high power supply rejection ratio (PSRR) performance and providing stability without requiring a large capacitor. By reducing the size of the capacitor, a less space on a die of an integrated circuit (IC), which may include other circuits, is required. The low noise and high stability performance are critical especially when the op-amp is used as a voltage reference for providing a steady and clean voltage reference to other circuits. In this description, when a signal is “amplified,” it is understood that the signal may be attenuated, buffered, or amplified.

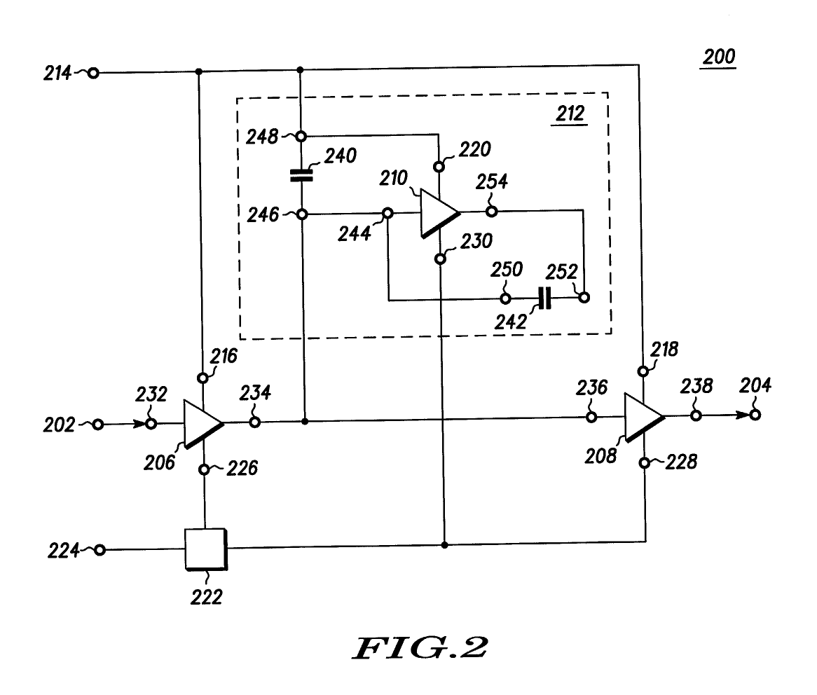

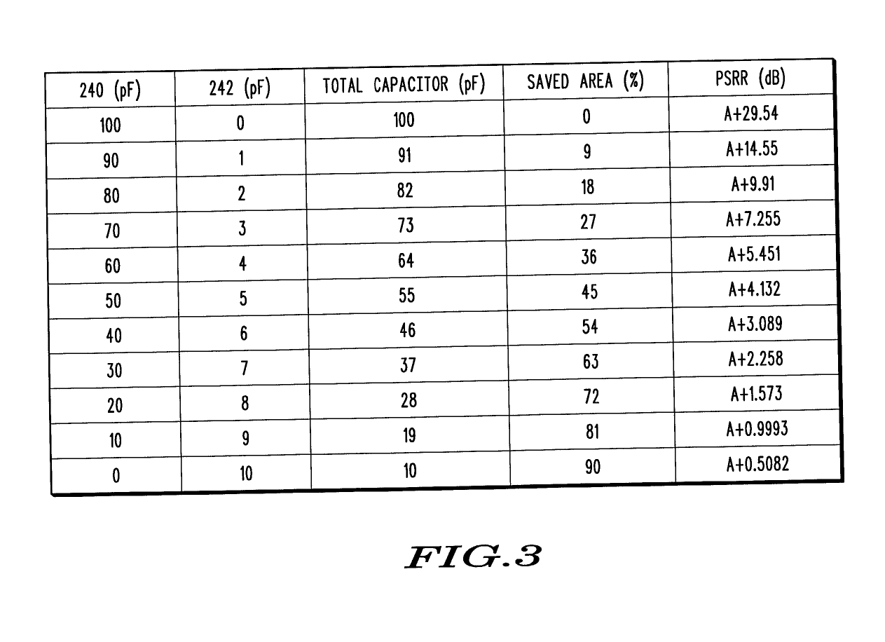

FIG. 2 illustrates a block diagram of the present invention (200) having an op-amp input (202) and an op-amp output (204) comprising a first amplifier (206), a second amplifier (208), and a third amplifier (210). The capacitor (102) utilized in prior art circuit (100) is replaced by the third amplifier circuit (212). Each amplifier receives power from a power supply line (214) at its power supply input (216, 218, 220). The power supply return path is provided by way of a return circuit (222) to a return terminal (224).

A first input (232) of the first amplifier (206) is coupled to the op-amp input (202), and the first amplifier receives an input signal entering the op-amp input through the first input. The first amplifier amplifies the input signal and provides a first amplified signal at a first output (234).

A second input (236) of the second amplifier (208) is coupled to the first output (234), and the second amplifier receives the first amplified signal from the first amplifier through the second input. The second amplifier amplifies the first amplified signal and provides a second amplified signal at a second output (238). The second output is coupled to the op-amp output (204), and an output signal present at the op-amp output is the desired signal to be used as the amplified signal.

The third amplifier (210) having a first capacitor (240) and a second capacitor (242), placed in parallel to the second amplifier (208), provides a desired Miller capacitance and produces desired PSRR and stability performance of the op-amp without requiring a large capacitor. A third input (244) of the third amplifier is coupled to the first output (234). A first terminal (246) of the first capacitor is also coupled to the third input. A second terminal (248) of the first capacitor is coupled to the power supply input (220) of the third amplifier which is coupled to the power supply line (214). A third terminal (250) of the second capacitor is also coupled to the third input. A fourth terminal (252) of the second capacitor is coupled to a third output (254) of the third amplifier. Unlike the second amplifier, the output signal from the third amplifier is not used as an output signal for the op-amp (200). The third amplifier is used as a dummy stage for the op-amp to provide desired PSRR and stability for the op-amp, and its output, the third output (254), is decoupled from the second output (238) of the second amplifier which is used as the output for the op-amp.

The following example illustrates an operation of the present invention used a voltage reference circuit.

A reference voltage signal is applied to the op-amp input (202). The voltage that is equal to this reference voltage signal appears at the op-amp output (204) to be used a reference voltage for other circuits requiring a reference voltage. The first amplifier senses the voltage and buffers this reference voltage signal to provide isolation between its input, the first input (202), and its output, the first output (234), to reduce loading of the reference voltage signal. The first output (234) is simultaneously coupled to both the second (208) and the third (210) amplifiers. The second amplifier (208) provides additional buffering and isolation between the second input (236) and the second output (238), which is coupled to the op-amp output (204). The first capacitor (240) is connected between the power supply line (214) and the first output (234) to improve power supply rejection ratio. The third amplifier is used as a dummy stage to provide Miller capacitance to the first amplifier for stability improvement by connecting the second capacitor (242) between the input (244) and output (254) of the third amplifier (210). Normally, this configuration, having a capacitor between the input and the output of an amplifier in addition to having a capacitor between power supply and the input, is not utilized. In this configuration, the power supply noise coupled through the first capacitor will appear at the output through the second capacitor and degrades the signal quality at the output. The noise at the output can also couple back to the power supply and contaminate the supply through the same path. However, in the present invention, the desired Miller capacitance is provided using the dummy stage (210) whose output (254) is not used to provide the reference voltage. Therefore, the effect of the noise coupling between the actual output, the op-amp out put (204), and the power supply through the Miller capacitor is significantly reduced.

Compared to a prior art circuit, the total capacitance required for the present invention to achieve similar performance in stability is decreased proportionately to the gain of the third amplifier, the dummy stage, while controlling the PSRR performance. The total effective capacitance of the present invention, Cₜₒₜₐₗ may be calculated by adding the first capacitance and the product of the dummy stage gain and the second capacitance, namely:

Cₜₒₜₐₗ=C1+A*C2,

where C1 is the capacitance of the capacitor 240, C2 is the capacitance of the capacitor 242, and A is the gain of the dummy stage. Assuming a total capacitance required to achieve the desired stability were 100 pF in the prior art circuit, the same stability and total effective capacitance can be achieved by the present invention by the combination of C1 and A*C2. If A is set to 10 and C1 to 10 pF, then C2 only needs to be 9 pF in order to achieve the total effective capacitance of 100 pF thereby achieving the desired stability. Therefore, by utilizing the total of 19 pF, this circuit is able to achieve the effectiveness of 100 pF. Because this combination of capacitance and gain also determines the PSRR of the circuit, the stability, PSRR, and the capacitor area reduced can be balanced by the designer of the circuit. Various combination of capacitor values to achieve 100 pF with the dummy stage gain of 10 is shown in FIG. 3 along with the PSRR of each combination and the capacitor area reduced. Because a capacitor requires relative large space in an integrated circuit die, a reduction in capacitance is particularly relevant for an integrated circuit application.

While the preferred embodiment of the invention suitable for a voltage reference application has been illustrated and described, it is to be understood that the invention is not so limited. Numerous modifications, changes, variations, substitutions and equivalents will occur to those skilled in the art without departing from the broad scope of the present invention as defined by the appended claims.

What is claimed is:

1. An operational amplifier (op-amp) circuit having a high power supply rejection ratio (PSRR) performance and providing stability, the op-amp circuit having an op-amp input and an op-amp output comprising:
a power supply line;
a first amplifier having a first input, a first output, and a first supply input, the first input coupled to the op-amp input for receiving an input signal, the first supply input coupled to the power supply line, the first amplifier amplifying the input signal entering from the first input and providing a first amplified signal at the first output;
a second amplifier having a second input, a second output, and a second supply input, the second input coupled to the first output, the second supply input coupled to the power supply line, the second output coupled to the op-amp output, the second amplifier amplifying the first amplified signal entering from the second input and providing a second amplified signal at the second output; and,
a third amplifier having a third input, a third output, and a third supply input, the third input coupled to the first output, the third supply input coupled to the power supply line, the third amplifier providing a Miller capacitance to the first amplifier.

2. An op-amp according to claim 1 further comprising a first capacitor having a first terminal and a second terminal, the first terminal coupled to the power supply line, the second terminal coupled to the first output.

3. An op-amp according to claim 1 further comprising a second capacitor having a third terminal and a fourth terminal, the third terminal coupled to the first output, the fourth terminal coupled to the third output.

4. An op-amp according to claim 1 wherein the second output is decoupled from the third output.

5. An op-amp circuit of claim 1 wherein the op-amp input is a pair of differential inputs.

6. An op-amp circuit of claim 1 wherein the op-amp output is a pair of differential outputs.

7. An op-amp circuit of claim 1 wherein the op-amp circuit is constructed on a single die of an integrated circuit (IC).

8. An op-amp according to claim 1 wherein the op-amp is utilized to provide a voltage reference.
